(19) United States
(12) Patent Application Publication
(10) Pub. No.: US 2024/0333230 A1
(43) Pub. Date: Oct. 3, 2024

(54) POWER LEVEL DETECTOR CIRCUIT WITH TEMPERATURE-DEPENDENCE REDUCTION

(71) Applicant: TEXAS INSTRUMENTS INCORPORATED, Dallas, TX (US)

(72) Inventors: TOLGA DINC, DALLAS, TX (US); SWAMINATHAN SANKARAN, Plano, TX (US)

(21) Appl. No.: 18/192,916

(22) Filed: Mar. 30, 2023

(51) Int. Cl. H03F 1/30; H03F 3/195; H03F 3/24

(52) U.S. Cl. CPC H03F 1/302; H03F 3/195; H03F 3/245; H03F 2200/105; H03F 2200/294; H03F 2200/451; H03F 2200/465; H03F 2200/84

(57) ABSTRACT

A circuit includes a radio frequency (RF) detector having an RF detector input and an RF detector output. The RF detector is configured to provide a first signal at the RF detector output responsive to a second signal at the RF detector input. The circuit further includes a processing circuit having a processing terminal coupled to the RF detector output. The processing circuit is configured to provide a third signal at the terminal based on scaling the first signal by a factor that is proportional to temperature.

### BACKGROUND

A power level detector circuit can detect the power level of an input signal, and generate an output signal having a signal level (e.g . . . amplitude) that represents Reducing the dependence on temperature would permit the power level detector circuit to provide an output signal that is a more accurate representation of the power level of its input signal.

### SUMMARY

In one example, a circuit includes a radio frequency (RF) detector and a thermal voltage (V_{T}) multiplication circuit. The RF detector has an RF detector input and an RF detector output. The V_{T} multiplier circuit has a multiplier terminal coupled to the RF detector output.

In another example, a circuit includes an RF detector having an RF detector input and an RF detector output. The RF detector is configured to provide a first signal at the RF detector output responsive to a second signal at the RF detector input. The circuit further includes a processing circuit having a processing terminal coupled to the RF detector output. The processing circuit is configured to provide a third signal at the terminal based on scaling the first signal by a factor that is proportional to temperature.

In yet another example, a power detector circuit includes a first BJT, a second BJT, a third BJT, a current mirror, a first transistor, a second transistor, and a resistor. The first BJT has a first base terminal and a first collector terminal. The first base terminal is coupled to a power detector input. The current mirror has a current mirror input and a current mirror output. The current mirror input is coupled to the first collector terminal. The second BJT is diode-connected and is coupled to the current mirror output. The first transistor is coupled between the current mirror output and the second BJT. The first transistor has a first control terminal and a first current terminal coupled to the current mirror output. The third BJT is diode-connected. The second and third BJTs have different current densities. The second transistor has a second current terminal coupled to a power detector output. The second transistor has a second control terminal coupled to the first control terminal. The resistor is coupled between the second transistor and the third BJT.

### BRIEF DESCRIPTION OF THE DRAWINGS

FIG. 1 is a schematic diagram of an example system including a power detector circuit.

FIG. 2 is a graph illustrating example variations of a power detection signal with respect to power and temperature provided by an example power detector circuit.

FIG. 3 is a schematic diagram of an example power detector circuit that includes a thermal voltage (Vr) multiplier circuit.

FIG. 4 is a schematic diagram illustrating example internal components of the power detector circuit of FIG. 3.

FIG. 5 is a schematic diagram of an example power detector circuit including a V_{T} multiplier circuit.

FIG. 6 is a schematic diagram of an example power detector circuit that includes two V_{T} multiplier circuits.

FIG. 7 is a schematic diagram illustrating example internal components of the power detector circuit of FIG. 6

FIG. 8 is a schematic diagram illustrating an example power detector circuit.

FIG. 9 is a graph illustrating example variations of a power detection signal with respect to power and temperature provided by the power detector circuit of FIG. 7.

### DETAILED DESCRIPTION

The same reference numbers or other reference designators are used in the drawings to designate the same or similar (either by function and/or structure) features.

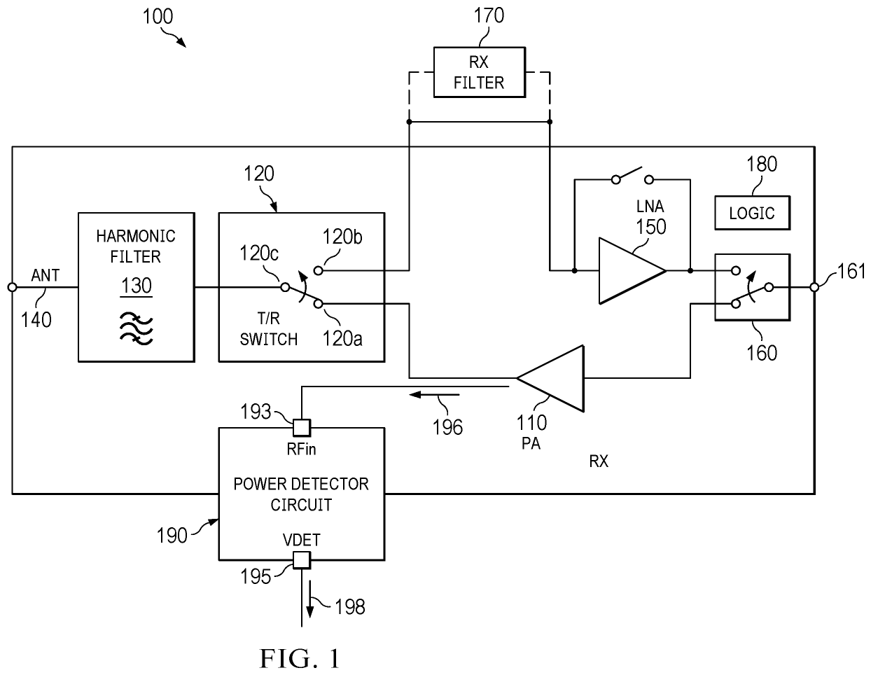

FIG. 1 is a schematic diagram of a system 100 in accordance with an example. System 100 includes a power amplifier (PA) 110, a transmit/receive (T/R) switch 120, a harmonic filter 130, an antenna 140, a low noise amplifier (LNA) 150, and a switch 160. The switch 160 can be a single pole double throw (SPDT) switch in which a terminal 161 of system 100 can be connected to either the input of the power amplifier 110 or the output of the LNA 150. The output of the power amplifier 110 is coupled to a terminal 120a of the T/R switch 120. Another terminal 120b of the switch 120 can be coupled to an input of the LNA 150, possibly via a filter 170 (if present). Another terminal 120c of the T/R switch 120 is coupled to the harmonic filter 130. The harmonic filter 130 is coupled to the antenna 140. System 100 can also include logic 180 to control the states of switches 120 and 160. Circuitry (not shown) can be coupled via terminal 161 to switch 160.

The system 100 in FIG. 1 may be illustrative of a transceiver in which a signal (e.g., a radio frequency (RF) signal) can be amplified by the PA 110 and transmitted by antenna 140 or received from antenna 140 and amplified by LNA 150. Through terminal 161, system 100 can be coupled to other circuitry, such as processing circuitry, to process signals received by antenna 140 and/or generate signals to be transmitted by antenna 140.

System 100 also includes a power detector circuit 190 having an RF input 193 and a detection output 195 (also labelled VDET). The RF input 193 can be indirectly coupled (e.g., capacitively coupled, etc.) to the output of the PA 110 or directly connected to the output of the PA 110 to receive a signal 196. The power detector circuit 190 produces a power detection signal 198, which can be in the form of a voltage or a current signal, at detection output 195. The signal level of power detection signal 198 (e.g., a voltage level, a current level, etc.) can represent the power level of the signal 196 and/or a signal provided by the PA 110. In some examples, the detection output 195 can be coupled to circuitry (not shown) that can control the output power level of the PA 110 based on the signal level of the signal 198 at detection output 195.

In some examples, the power detector circuit 190 includes a radio frequency (RF) detector that receives signal 196 having a voltage level V_{RF} and generates power detection signal 198 as a function of a square of the voltage level of signal 196 (V_{RF}²) and an amplification property of the RF detector, as follows:

$$S \approx {( G * {V}_{RF} )}^{2} \qquad ( Equation 1 )$$

In Equation 1, S represents a signal level of power detection signal 198, which can be a current value or a voltage value. Also, G represents the amplification property of the RF detector, such as transconductance and voltage amplification gain. Because the power of signal 196, and the output power level of the PA 110, can each be represented by V_{RF}², the signal level of power detection signal 198 can represent the output power level of the PA 110.

The accuracy of power detection signal 198 in representing the output power level of the PA 110, however, can be affected by various factors, such as the temperature dependence of the amplification property G. Because of the temperature dependence, the amplification property may vary with temperature. Accordingly, even for the same output power level (and same V_{RF}²), the signal level of power detection signal 198 may vary under different temperatures, which leads to errors in the power detection signal 198. The temperature dependence, and the resulting errors, can be further amplified because the signal level of power detection signal 198 relates to the square of the transconductance/voltage amplification gain, as shown in Equation 1.

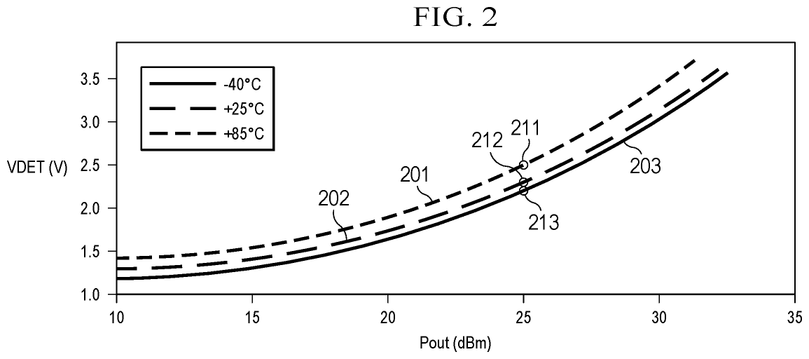

FIG. 2 is a graph illustrating example relationships between the voltage level of power detection signal 198 and the output power level of the PA 110 of FIG. 1 for three different temperatures. Plot 201 represents an example relationship at a temperature of −40° C. Plot 202 represents an example relationship at a temperature of +25° C. Plot 203 represents an example relationship at a temperature of +85° C. As shown in plots 201, 202, and 203, even for the same output power level, the voltage level of power detection signal 198 varies with temperature. For example, for an output power level of 25 dBm, the voltage level of power detection signal 198 can be at 2.2V at a temperature of −40° C. (labelled with reference numeral 211), 2.3V at a temperature of +25° C. (labelled with reference numeral 212), and 2.5V at a temperature of +85° C. (labelled with reference numeral 213). Accordingly, the temperature dependency introduces errors in power detection signal 198.

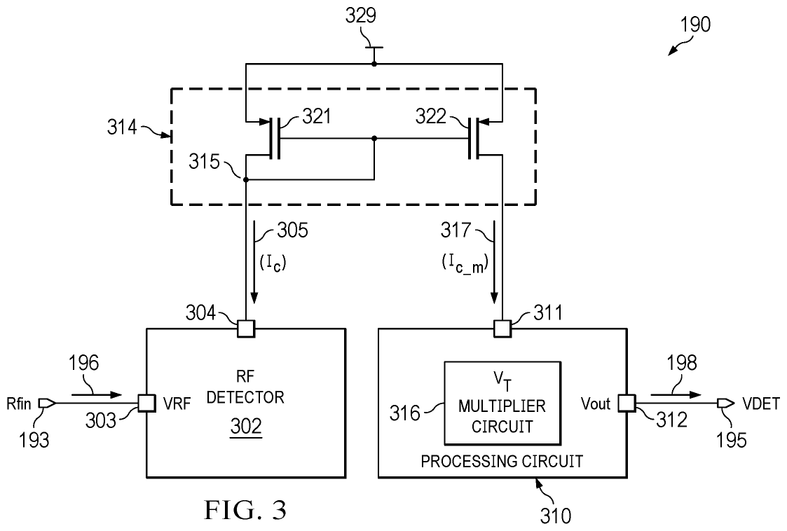

FIG. 3 is a schematic diagram of an example of the power detector circuit 190 having reduced temperature dependence. In this example, the power detector circuit 190 can include an RF detector 302, a processing circuit 310, and a current mirror 314. The RF detector 302 can have an input 303 (coupled to the RF input 193) and an output 304. The RF detector 302 can generate a current signal 305 (also labelled I_{c}) at output 304 responsive to signal 196 at RF input 193. In a case where signal 196 has a voltage level V_{RF}, the magnitude of current signal I_{c} can be a function of V_{RF}² as described above in Equation 1.

Also, the current mirror 314 has a current mirror input 315 and a current mirror output 317. The current mirror input 315 is coupled to the RF detector output 304. The current mirror 314 can include a first transistor 321 and a second transistor 322. The gates of transistors 321 and 322 are coupled together and to a first current terminal (e.g., drain) of transistor 321. The first current terminal of transistor 321 can be coupled to the current mirror input 315. Second current terminals (e.g., sources) of transistors 321 and 322 can be coupled together and to a supply voltage terminal 329. The first current terminal (e.g., drain) of transistor 322 can be coupled to the current mirror output 317. The current mirror 314 can receive the current signal I_{c} at current mirror input 315 and provide a replica current signal 319 (also labelled I_{c_m}) at current mirror output 317. In some examples, current signal I_{c_m} can be a scaled version of the current signal I_{c}. In some examples, the transistors 321 and 322 can be P-type field effect transistors (PFET), and the current mirror 314 can be coupled between output 304 and supply voltage terminal 329 as shown in FIG. 3. In some examples, the transistors 321 and 322 can be N-type field effect transistors (NFET), and the current mirror 314 can be coupled between output 304 can be coupled between output 304 and ground.

In addition, the processing circuit 310 has an input 311 and an output 322. Input 311 of the processing circuit 310 is coupled to current mirror output 317 to receive current signal I_{c_m}. Output 322 of the processing circuit 310 is coupled to detection output 195. The processing circuit 310 can provide power detection signal 198 responsive to the replica current signal I_{c_m}. In addition, the processing circuit 310 can reduce the temperature dependency of power detection signal 198 based on scaling the replica current signal I_{c_m} by a factor that is proportional to temperature, and providing the power detection signal 198 based on the scaled replica current signal I_{c_m}. For example, as shown in FIG. 3, the processing circuit 310 can include a thermal voltage (V_{T}) multiplier circuit 316 that can scale the replica current signal I_{c_m} by a factor based on V_{T}, which is proportional to temperature.

The RF detector 302 converts signal 196 derived from the output of the PA 110 and received on its input 303 to a current signal I_{c} at its output 304. In some examples, RF detector 302 can generate the current signal I_{c} as proportional to V_{RF}². In some examples, the RF detector can include one or more BJTs, and the current signal I_{c} generated by the one or more BJTs, as well as the replica current signal I_{c_m}, can be inversely proportional to the square of thermal voltage V_{T} (V+2). As the processing circuit 310 scales the replica current signal I_{c_m} by a factor based on V_{T}, and generates the power detection signal 198 based on the scaled replica current signal I_{c_m}, the power detection signal 198 can become a function of V_{T} rather than V_{T}². Because V_{T} is proportional to temperature, the scaling of I_{c_m} by a factor based on V_{T} by the processing circuit 310 can reduce the temperature dependency of the power detection signal 198 (e.g., from a dependence on a square of temperature to a linear dependence on temperature). As to be described below, additional techniques, such as diode biasing, can be implemented to combine with the V_{T} multiplier circuit 316 to further reduce the linear temperature dependence of the power detection signal 198 (e.g., to substantially temperature independence).

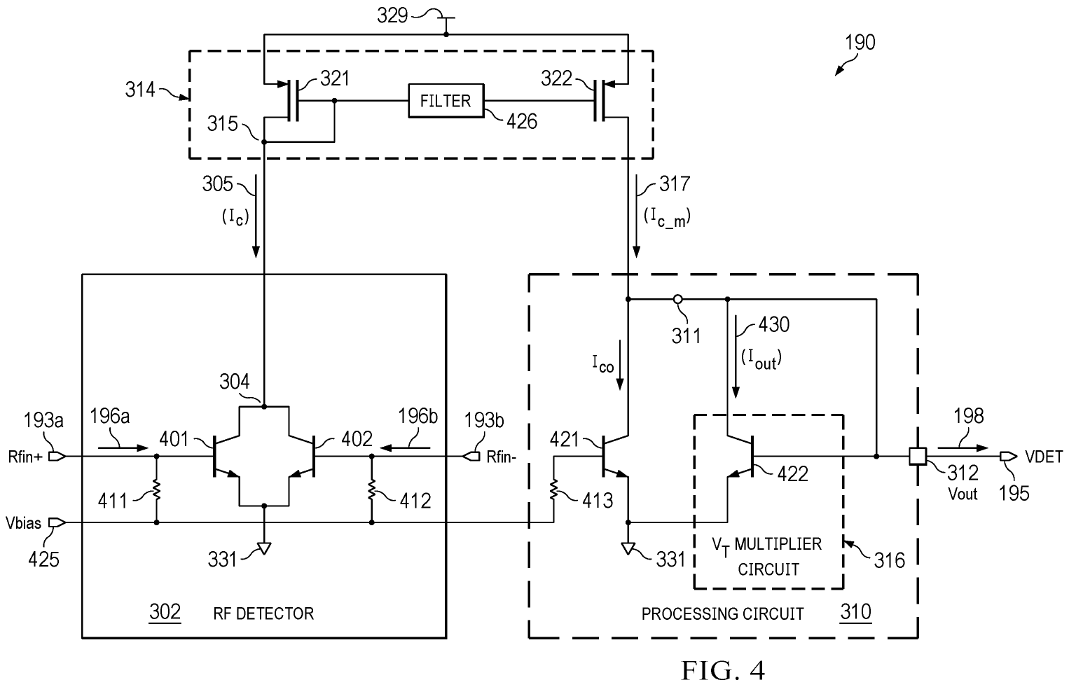

FIG. 4 is a schematic diagram illustrating example internal components of the RF detector 302 and the processing circuit 316 of the power detector circuit 190. In this example, RF detector 302 includes transistors 401 and 402 and resistors 411 and 412. The V_{T} multiplier circuit 316 includes a transistor 422. Besides the V_{T} multiplier circuit 316, the processing circuit 310 includes a transistor 421 and a resistor 413. Transistors 401, 402, 421, and 422 can be BJTs (e.g., such as NPNs as shown in FIG. 4, or PNPs). Also, the power detector circuit 190 can include filter 426. The filter 426 can be part of the current mirror 314 (e.g., coupled to the gate of FETs 321 and 322, as shown in FIG. 4) or can be external to the current mirror 314 (e.g., coupled to the current mirror input 315 or the current mirror output 317).

The emitters of transistors 401 and 402 can be coupled together and to a reference terminal 331 (e.g., ground). The collectors of transistors 401 and 402 can be coupled together and to the output 304 of RF detector 302. In the example of FIG. 4, transistors 401 and 402 of RF detector 302 provide a differential input. The PA 110 can have a differential output, which is coupled as described above to the differential input of RF detector 302. Accordingly, the RF input 193 of FIGS. 1 and 3 includes a RF input 193a (labelled RFin+) and RF input 193b (labelled RFin−). RF input 193a can receive signal 196a, and RF input 193b can receive signal 196b, where signals 196a and 196b can be a pair of differential signals coupled from the output PA 110. The RF input 193a is coupled to the base of transistor 401, and the RF input 193b is coupled to the base of transistor 402. Also, the bases of transistors 401 and 402 are coupled to a bias terminal 425, which can receive a bias voltage Vbias. Resistor 411 is coupled between the bias terminal 425 and the base of transistor 401, and resistor 412 is coupled between the bias terminal 425 and the base of transistor 402.

The collectors of transistors 421 and 422 are coupled to the input 311 and to the base of transistor 422, which also is coupled to the output 312 of the V_{T} multiplier circuit 316 (and detection output 195). Transistor 422 is diode-connected transistor, where the base and collector of the transistor 422 are coupled together and can have the same voltage. The emitters of transistors 421 and 422 are coupled together and to the reference terminal 331 (ground). The V_{be} voltage (the voltage between the base and emitter) of transistor 422 can provide power detection signal 198. Also, the base of transistor 421 is biased based on the same bias voltage Vbias as for transistors 401 and 402. Resistor 402 is coupled between the bias voltage V_{bias} and the base of transistor 421.

The current I_{c} through the RF detector's input pair of transistors 401 and 402 is given by:

$${I}_{c} = {I}_{s} * {e}^{\frac{{V}_{bias} + {V}_{in}}{{V}_{T}}} \qquad ( Equation 2 )$$

In Equation 2, Iₛ is the saturation current of transistors 401 and 402, and Vᵢₙ is the differential input voltage to the RF detector. The differential input voltage can be a sinusoidal voltage having an amplitude equal to V_{RF} having an angular frequency ω as follows:

$${V}_{in} = {V}_{RF} * cos ( ω t ) \qquad ( Equation 3 )$$

The Maclaurin Series expansion for e^{x} is:

$${e}^{x} = 1 + x + \frac{{x}^{2}}{2 !} + \frac{{x}^{3}}{3 !} + … \qquad ( Equation 4 )$$

Using the expansion of ex from Equation 4, Equation 2 can

$${I}_{c} = {I}_{c 0} ( 1 + \frac{{V}_{in}}{{V}_{T}} + \frac{{{V}_{in}}^{2}}{2 * {{V}_{T}}^{2}} + \frac{{{V}_{in}}^{3}}{6 * {{V}_{T}}^{3}} + … ) \qquad ( Equation 5 )$$

In Equation 5, the current I_{c0} in Equation 5 represents the bias component of current I_{c} in RF detector 302 due to the bias voltage V_{bias}, as follows:

$${I}_{c 0} = {I}_{s} * {e}^{\frac{Vbias}{{V}_{T}}} \qquad ( Equation 6 )$$

Substituting Equation 3 into Equation 5:

$${I}_{c} = {I}_{c 0} + \frac{{I}_{c 0} * {V}_{RF} * cos ( ω t )}{{V}_{T}} + \frac{{I}_{c 0} * {( {V}_{RF} * cos ( ω t ) )}^{2}}{2 * {{V}_{T}}^{2}} + … \qquad ( Equation 7 )$$

Equation 7 can be rewritten into:

$${I}_{c} = {I}_{c 0} + \frac{{I}_{c 0} * {{V}_{RF}}^{2}}{4 * {{V}_{T}}^{2}} + \frac{{I}_{c 0} * {V}_{RF} * cos ( ω t )}{2 * {{V}_{T}}^{2}} + \frac{{I}_{c 0} * {{V}_{RF}}^{2} * cos ( 2 ω t )}{4 * {{V}_{T}}^{2}} + … \qquad ( Equation 8 )$$

The output current I_{c} or the replica current I_{c_m} can be low-pass filtered by the filter 426. The filtering can be performed on, for example, the gates of FETs 321/322 of the current mirror 314. As a result of the low-pass filtering, AC components of I_{c} having the angular frequency ω (or multiples of ω) can be filtered out, while the DC components

$${I}_{c 0} + \frac{{I}_{c 0} * {{V}_{RF}}^{2}}{4 * {{V}_{T}}^{2}}$$

can remain. The current mirror 314 can provide a replica current I_{c_m} that is a replica (or a scaled version) of I_{c}. Accordingly, I_{c_m} can have a magnitude equal to or is a scaled version of

$${I}_{c 0} + \frac{{I}_{c 0} * {{V}_{RF}}^{2}}{4 * {{V}_{T}}^{2}} .$$

Also, transistors 421 and 422 can split the replica current I_{c_m}. In some examples, transistors 421 can biased using the same voltage Vbias as for transistors 401 and 402, and can divert the current I_{c0} (or a scaled version of it) from I_{c_m}. Accordingly, a current 430 (labelled Iₒᵤₜ in FIG. 4) that flows into transistor 422 from current mirror's output 317 can be as follows:

$${I}_{out} = \frac{{I}_{c 0} * {{V}_{RF}}^{2}}{4 * {{V}_{T}}^{2}} \qquad ( Equation 9 )$$

In Equation 9, the term

$$\frac{{I}_{c 0}}{4 * {{V}_{T}}^{2}}$$

can represent the amplification property G of RF detector 302 in Equation 1. The output current Iₒᵤₜ thus has a magnitude given by approximately a product of G and the square of V_{RF} (V_{RF}²), and the output current I_{c} can be approximately proportional to V_{RF} at a particular temperature. However, since the amplification property G

$$( \frac{{I}_{c 0}}{4 * {{V}_{T}}^{2}} )$$

is also inversely proportional to the square of the thermal voltage (V_{T}²), the output current Iₒᵤₜ also has a strong temperature dependency, and may vary at different temperatures even for the same V_{RF}². If power detection signal 198 is generated directly from output current Iₒᵤₜ without any temperature compensation processing, power detection signal 198 may also be inversely proportional to V_{T}² and have a strong temperature dependency.

V_{T} multiplier circuit 316 can reduce the temperature dependence of power detection signal 198 by performing temperature compensation processing on Iₒᵤₜ. Specifically, V_{T} multiplier circuit 316 can convert the output current Iₒᵤₜ to a voltage signal for power detection signal 198, and as part of the conversion, scale the output current Iₒᵤₜ by a factor related to V_{T}. As described above, Iout is inversely proportional to V_{T}². By scaling the output current Iₒᵤₜ by a factor related to V_{T}, the scaled output current Iₒᵤₜ can become inversely proportion to V_{T}. As power detection signal 198 is generated from the scaled output current Iₒᵤₜ, the temperature dependence of power detection signal 198 can be reduced.

Specifically, the current Iout flows into diode-connected transistor 422 as the collector current. The V_{be} voltage of the diode-connected transistor 422, which can provide power detection signal 198, can be related to the current Iₒᵤₜ as follows:

$${V}_{be , 422} = {V}_{T} * ln ( \frac{{I}_{out}}{{I}_{s}} ) \qquad ( Equation 10 )$$

The term

$$ln ( \frac{{I}_{out}}{{I}_{s}} ) ,$$

which represents the natural logarithm of the ratio

$$\frac{{I}_{out}}{{I}_{s}} ,$$

can be approximately proportion to Iₒᵤₜ. Accordingly, Equation 10 can be rewritten as follows:

$${V}_{be , 422} = {V}_{T} * n * {I}_{out} \qquad ( Equation 11 )$$

In Equation 11, n is a scaling factor which, when multiplies with Iₒᵤₜ, can approximate

$$ln ( \frac{{I}_{out}}{{I}_{s}} ) .$$

According, oy converting the current Iₒᵤₜ to the V_{be} voltage, V_{T} multiplier circuit 316 can scale the current Iₒᵤₜ by a factor based on V_{T}. Substituting Equation 9 into Equation 11 becomes:

$${V}_{be , 422} = {V}_{T} * n * \frac{{I}_{c 0} * {V}_{{RF}^{2}}}{4 * {V}_{{T}^{2}}} = n * \frac{{I}_{c 0} * {V}_{{RF}^{2}}}{4 * {V}_{T}} \qquad ( Equation 12 )$$

Accordingly, the V_{be} voltage of the diode-connected transistor 422, which can provide power detection signal 198, can be inversely proportional to V_{T}. Compared with Iₒᵤₜ which is inversely proportional to V_{T}², the temperature dependence of power detection signal 198 can be reduced.

In the example shown in FIG. 4, transistors 401, 402, 421, 422 are NPN, and the transistors 321 and 322 of the current mirror 314 are PFETs. In some other examples, transistors 401, 402, 421, and 422 are PNP, and the transistors 321 and 322 of the current mirror 314 are NFETs. In such examples, PNP transistors 401 and 402 can be coupled between the supply voltage terminal 329 and output 304, and the current mirror 314 can be coupled between output 304 and the reference terminal 331. Also, PNP transistors 421 and 422 can be coupled between the supply voltage terminal 329 and the current mirror output 317.

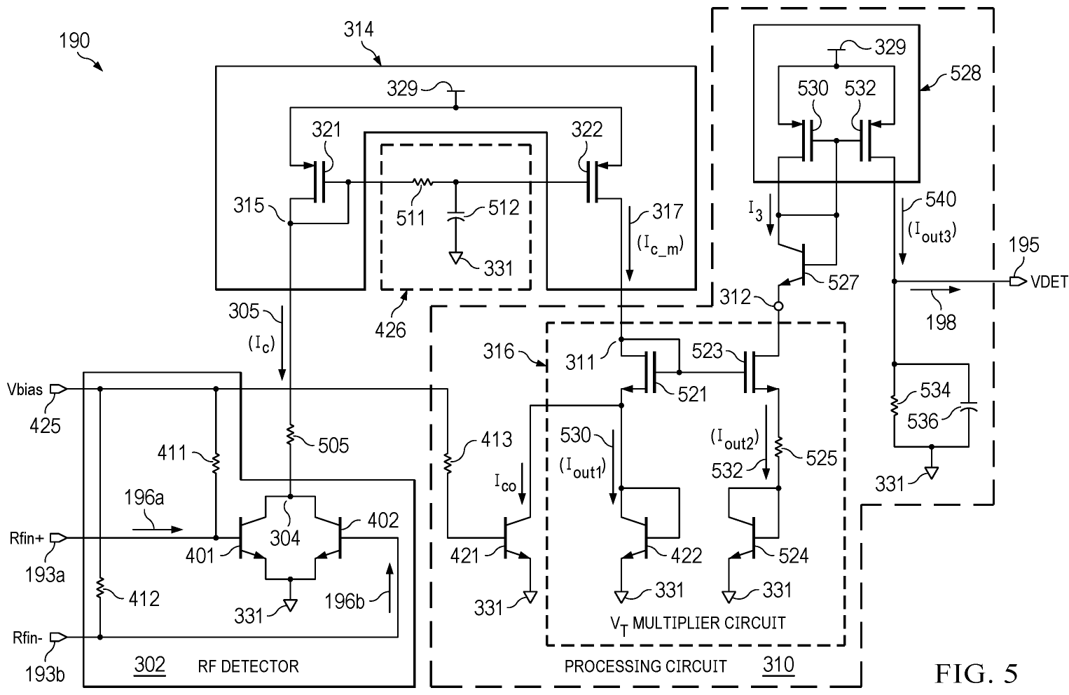

FIG. 5 is a schematic diagram of another example of the power detector circuit 190. In addition to transistor 422, the V_{T} multiplier circuit 316 includes transistors 521, 523, and 524 and resistor 525. The power detector circuit 190 in FIG. 5 also includes resistors 505 and 534, capacitor 536, filter 426, transistor 527, and current mirror 528. Resistor 505 is coupled between the output 304 of RF detector 302 and the current mirror input 315 of current mirror 314.

Filter 426 can be coupled between the current mirror input 315 of current mirror 314 and the current mirror's output 317. As described above, filter 426 can be a low-pass filter. In the example of FIG. 5, filter 426 can include a resistor 511 coupled to a capacitor 512. The combination of current mirror 314 and filter 510 can generate a first output current 530 (labelled Iₒᵤₜ₁) with the DC components

$${I}_{c 0} + \frac{{I}_{c 0} * {V}_{{RF}^{2}}}{4 * {V}_{{T}^{2}}}$$

of I_{c_m} retained, and the AC components attenuated or eliminated as described above. The first output current Iₒᵤₜ₁ flows through transistor 521 and diode-connected transistor 422.

Within the V_{T} multiplier circuit 316 of FIG. 5, transistor 524 can be a BJT and transistors 521 and 523 can be NFETs. Transistor 524 is a diode-connected with its base is connected to its collector. Transistor 524 can be an NPN or a PNP and is of the same type as transistor 422. Transistor 521 can be coupled between the multiplier terminal 311 and the diode-connected transistor 422. The gates of transistors 521 and 523 are coupled together and the drain of transistor 521. Resistor 525 is coupled between transistor 523 and transistor 524.

The V_{T} multiplier circuit 316 of FIG. 5 can generate a second output current 532 (labelled Iₒᵤₜ₂) by scaling Iₒᵤₜ₁ by a factor based on V_{T} through the difference in the V_{be} voltages (ΔV_{be}) between transistors 422 and 524. Specifically, transistor 524 has a smaller current density than transistor 422. The size of transistor 524 is m times the size of transistor 422. In some examples, the size difference factor m ranges from 8 to 16. Because transistor 524 has a smaller current density than transistor 422, Iₒᵤₜ₂ can be different from Iₒᵤₜ₁. Also, the gate-to-source voltage (Vgs) of transistors 521 and 523 are approximately equal, which forces V_{be,422} to be approximately equal to a sum of the voltage across resistor 525 and V_{be,524}, the voltage across resistor 525 can be equal to ΔV_{be} between transistors 422 and 524. ΔV_{be} can be related to Iₒᵤₜ₂ and Iₒᵤₜ₁ as follows:

$${V}_{be , 422} - {V}_{be , 524} = Δ {V}_{be} ∝ {V}_{T} * ln ( \frac{{I}_{out 1}}{{I}_{C 2} {I}_{out 2}} ) \qquad ( Equation 13 )$$

The term I_{C2} refers to the DC biasing current flowing through transistor 523. The term

$$ln ( \frac{{I}_{out 1}}{{I}_{C 2} + {I}_{out 2}} ) ,$$

which represents the natural logarithm of the ratio

$$\frac{{I}_{out 1}}{{I}_{C 2} + {I}_{out 2}} ,$$

can be approximately proportion to Iₒᵤₜ₁. Accordingly, Equation 13 can be rewritten as follows:

$$Δ {V}_{be} = {V}_{T} * α * {I}_{out 1} \qquad ( Equation 14 )$$

In Equation 14, α is a scaling factor which, when multiplies with Iₒᵤₜ₁, can approximate

$$ln ( \frac{{I}_{out 1}}{{I}_{C 2} + {I}_{out 2}} ) .$$

The current Iₒᵤₜ₂ equals a ratio between ΔV_{be} and the resistance R of resistor 525, as follows:

$${I}_{out 2} = \frac{{V}_{T} * α}{{R}_{525}} * {I}_{out 1} = \frac{α}{{R}_{525}} * n * \frac{{I}_{c 0} * {V}_{{RF}^{2}}}{4 * {V}_{T}} \qquad ( Equation 15 )$$

Accordingly, as shown in Equation 15, the V_{T} multiplier circuit 316 of FIG. 5 can generate Iₒᵤₜ₂ by scaling Iₒᵤₜ₁ with a factor based on V_{T}, and reduce the temperature dependence of Iₒᵤₜ₂ with respect to Iₒᵤₜ₁.

In addition, processing circuit 310 includes a current mirror 528 that can generate a third output current 540 (labelled Iₒᵤₜ₃) as a replica (or a scaled version) of the second output current 532 (Iₒᵤₜ₂). Current mirror 528 includes transistors 530 and 532 (e.g., PFETs or NFETs) coupled together. Current mirror 528 also includes a diode-connected transistor 527 (e.g., an NPN) coupled to the gate/drain of transistor 530 to provide a diode voltage drop between the output 312 of the V_{T} multiplier circuit 316 and the current mirror 528. Because Iout from the V_{T} multiplier circuit 316 has a reduced V_{T} dependency as described above, replica current Iₒᵤₜ₃ similarly has a reduced V_{T} dependency.

Also, processing circuit 310 includes a resistor 534, and can generate power detection signal 198 as a voltage signal by injecting replica current Iₒᵤₜ₃ into resistor 534. The resistances of resistors 534 and 525 can have the same temperature dependence. For example, resistor 525 and 534 can be the same type of resistor. The temperature coefficients of resistors 525 and 534 can both be positive or both be negative. Such arrangements can reduce the temperature dependence of power detection signal 198 attributed to resistors 534 and 525. Specifically, the temperature dependence of resistor 525 can alter the current Iₒᵤₜ₂ through the resistor. For example, if resistor 525 has a positive temperature coefficient (resistance increases as temperature increases, and vice versa), then current Iₒᵤₜ₂ (which is the ΔV_{be} divided by the resistance of resistor 525) may decrease as temperature increases. If current Iₒᵤₜ₂ decreases with increasing temperature, then replica current Iₒᵤₜ₃ also decreases with increasing temperature. Because resistors 534 and 525 are the same type of resistor, the resistance of resistor 534 also increases with increasing temperature, which can compensate for the reduced replica current Iₒᵤₜ₃, and the voltage of power detection signal 198 can be maintained or at least have reduced temperature dependence. In some examples, processing circuit 310 may include a capacitor 536 coupled in parallel with resistor 536 to form a filter, to further reduce the fluctuation of power detection signal 198.

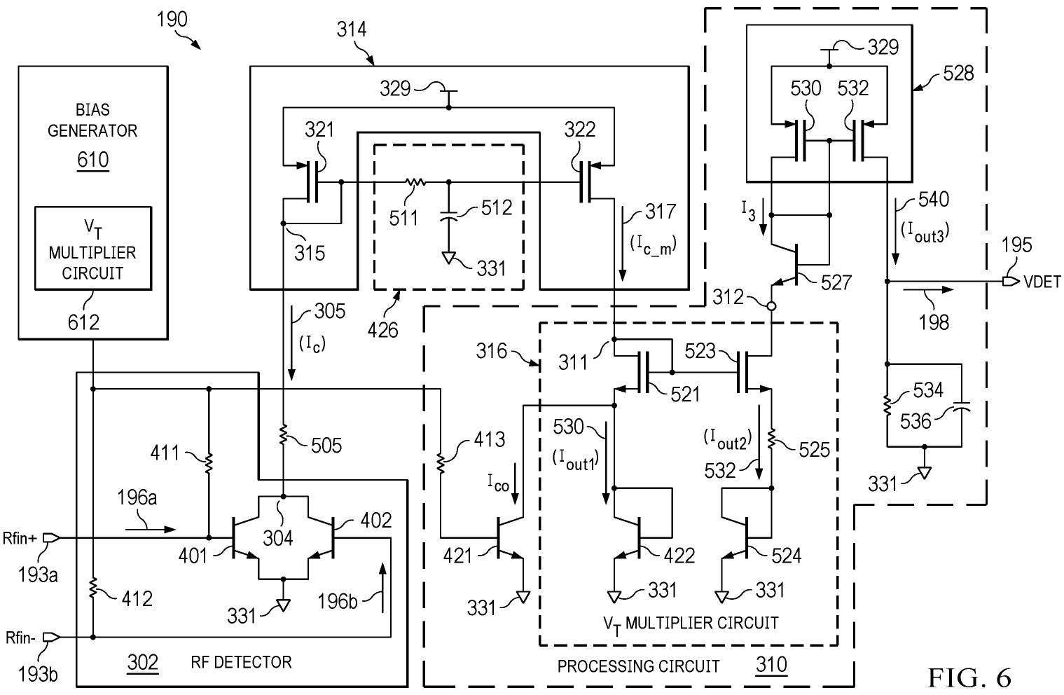

In addition to V_{T} multiplier circuit 316 to scale the output current of the current mirror 314 (Iₒᵤₜ in FIG. 4, Iₒᵤₜ₁ in FIG. 5), power detector circuit 190 can also include additional V_{T} multiplier circuit(s) to further reduce the temperature dependence. FIG. 6 is a schematic diagram of another example of the power detector circuit 190 including a bias generator 610 that includes an additional V_{T} multiplier circuit 612. The bias generator 610 biases transistors 401 and 402, and can scale the bias current component I_{c0} by a factor based on V_{T}. Accordingly, the Iₒᵤₜ (in FIG. 4) and Iₒᵤₜ₂ (in FIG. 5) can be scaled by V_{T}, and the temperature dependence of power detection signal 198 can be further reduced or substantially eliminated.

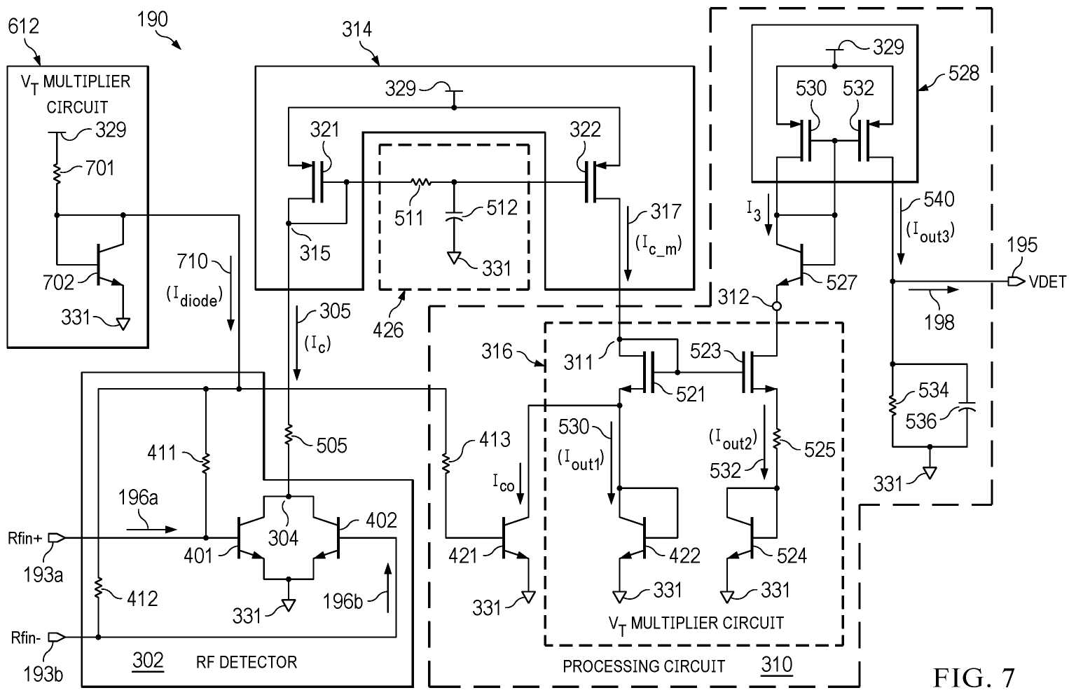

FIG. 7 is a schematic diagram illustrating the internal components of V_{T} multiplication circuit 612 of the bias generator 610. The example V_{T} multiplication circuit 612 can include a resistor 701 and a transistor 702. Transistor 702 can be an NPN or PNP and have the same type as transistors 401 and 402. Transistor 702 is diode-connected, with the base of transistor 702 coupled to its collector and to resistor 701. Resistor 701 is coupled between the supply voltage terminal 329 and the diode-connected transistor 702. Resistors 411, 412, and 413 are coupled between the collector of transistor 702 and the bases of their respective transistors 401, 402, and 421.

Transistor 402 can receive a current 710 (also labelled I_{diode}) from supply voltage terminal 329 through resistor 701. The V_{be} of transistor 702 is given by:

$${V}_{b e , 702} = {V}_{T} * ln ( \frac{{J}_{d i o d e}}{s} ) = {V}_{B G} - {V}_{T} * k \qquad ( Equation 16 )$$

V_{BG} is the bandgap voltage of silicon. I_{diode} can be related to the voltage V_{supply} at supply voltage terminal 329 and the resistance of resistor 701 as follows:

$${I}_{diode} = \frac{( {V}_{supply} - {V}_{be , 702} )}{{R}_{701}} = \frac{( {V}_{supply} - {V}_{BG} + {V}_{T} * k )}{{R}_{701}} \approx l * {V}_{T} \qquad ( Equation 17 )$$

Accordingly, I_{diode} can be a scaled version of V_{T}. The diode-connected transistor 702 and the transistors 401 and 402 of RF detector 302 form current mirrors in which the current through the diode-connected transistor 702 is mirrored as the bias current through of the transistors 401 and 402, and the bias current component I_{c0} can be equal to I_{diode} or can be a scaled version of I_{diode}. Substituting Equation 17 into Equations 12 and 15, it can be shown that the temperature dependence of Iₒᵤₜ and Iₒᵤₜ₂ can be further reduced from being proportional to 1/V_{T} to substantially temperature independence, while both Iₒᵤₜ and Iₒᵤₜ₂ remain proportional to V_{RF}²:

$${I}_{out} = n * \frac{{I}_{c 0} * {V}_{{RF}^{2}}}{4 * {V}_{T}} = n * \frac{l * {V}_{{T}^{*}} {V}_{{RF}^{2}}}{4 * {V}_{T}} = n * \frac{l * {V}_{{RF}^{2}}}{4} \qquad ( Equation 18 )$$

$$( Equation 19 )$$

$${I}_{out 2} = \frac{α}{R} * n * \frac{{I}_{c 0} * {V}_{{RF}^{2}}}{4 * {V}_{T}} = \frac{α}{R} * n * \frac{l * {V}_{{T}^{*}} {V}_{{RF}^{2}}}{4 * {V}_{T}} = \frac{α}{{R}_{525}} * n * \frac{l * {V}_{{RF}^{2}}}{4}$$

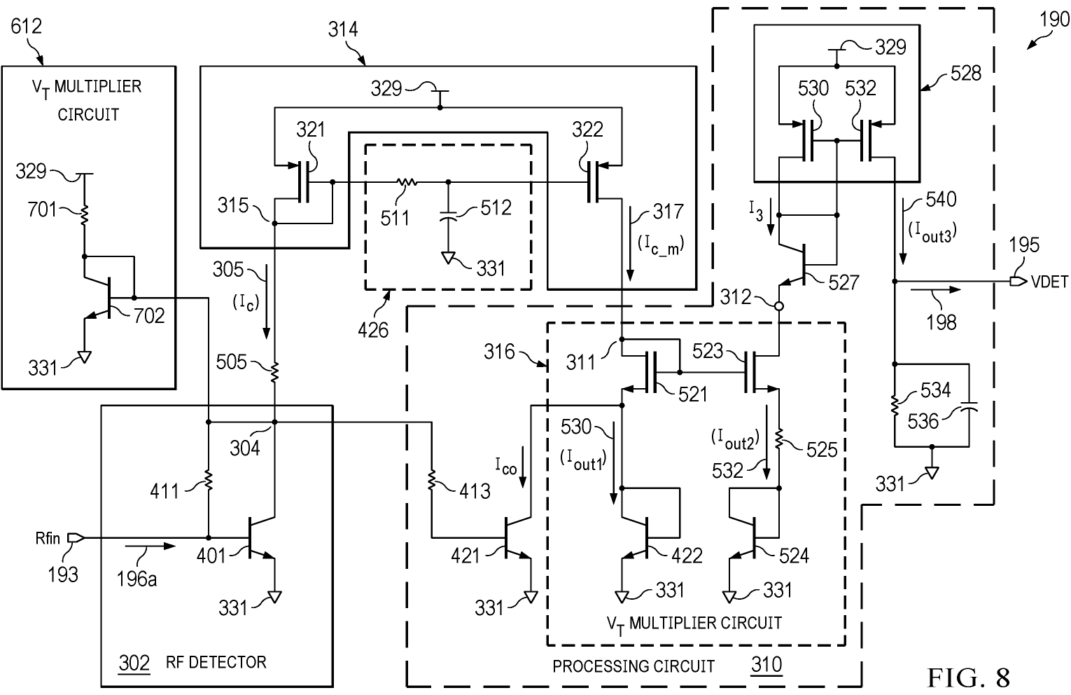

FIG. 8 is a schematic diagram of another example of power detector 190 in which RF detector 302 has a single-ended input. The single-ended RF detector 302 can be useful for a power amplifier 110 that has a singled-ended output (e.g., an output voltage referenced to the reference terminal 331. FIG. 8 is largely the same as FIG. 7 with the exception that RF detector 302 can include one transistor (e.g., transistor 304) instead of a pair of transistors. The rest of the circuitry and operation of the power detector circuit 190 of FIG. 8 is largely the same as described above.

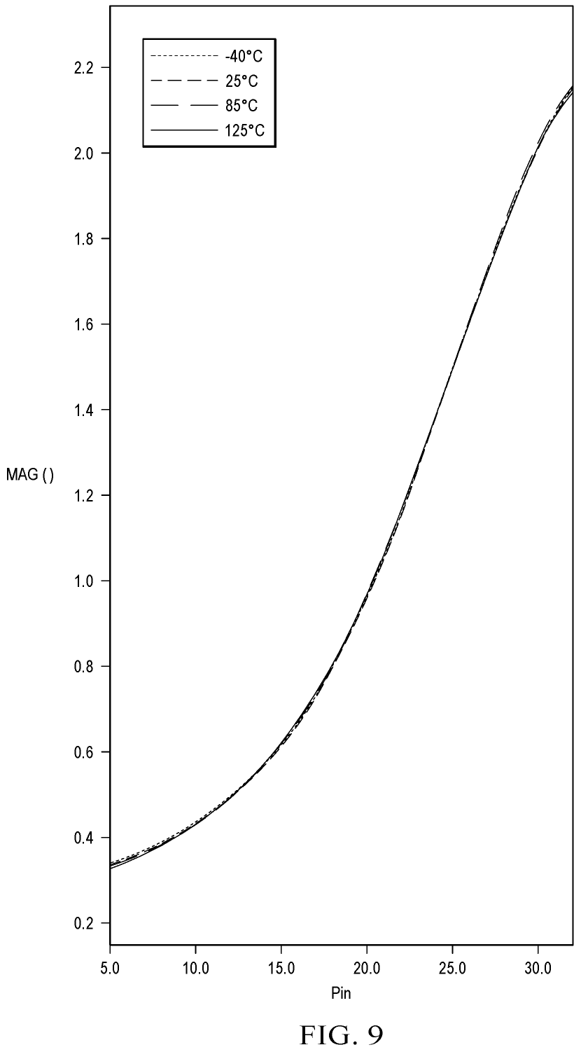

FIG. 9 is a graph illustrating example variations of example relationships between the voltage level of power detection signal 198 and the output power level of the PA 110 of FIG. 1 for multiple temperatures including −40° C., +25° C., +85° C., and +125° C. The power detection signal 198 in FIG. 9 is based on Iₒᵤₜ₂ of FIG. 7. As shown in FIG. 9, the voltage level of power detection signal 198 represents the output power level. For the same output power level, the voltage level of power detection signal 198 is substantially the same across temperatures.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and May be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used in place of one or more the transistors with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with one or more of the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A circuit, comprising:
a radio frequency (RF) detector having an RF detector input and an RF detector output; and
a thermal voltage (Vt) multiplier circuit having a multiplier terminal coupled to the RF detector output.

2. The circuit of claim 1, wherein the Vt multiplier circuit includes a diode-connected bipolar junction transistor (BJT) coupled to the multiplier terminal.

3. The circuit of claim 2, further comprising:
a current mirror having a current mirror input and a current mirror output, the current mirror input coupled to the RF detector output, and the current mirror output coupled to the multiplier terminal; and
a filter coupled between the current mirror input and the current mirror output.

4. The circuit of claim 2, wherein the Vt multiplier circuit has a multiplier output, the BJT is a first BJT, and the Vt multiplier circuit further includes a second diode-connected BJT coupled to the multiplier output, and the first and second diode-connected BJTs have different current densities.

5. The circuit of claim 4, wherein the Vt multiplier circuit further includes:
a first transistor coupled between the multiplier terminal and the first diode-connected BJT, the first transistor having a first control terminal coupled to the multiplier terminal;
a second transistor coupled to the multiplier output, the second transistor having a second control terminal coupled to the first control terminal; and
a resistor coupled between second transistor and the second diode-connected BJT.

6. The circuit of claim 5, wherein the Vt multiplier circuit is configured to generate a first voltage at the multiplier output based on a difference between a second voltage across the first diode-connected BJT and a third voltage across the second diode-connected BJT, and based on a resistance of the resistor.

7. The circuit of claim 5, further comprising a current mirror having a current mirror input and a current mirror output, the current mirror input coupled to a current terminal of the second transistor, and the current mirror output coupled to the multiplier output.

8. The circuit of claim 1, wherein the RF detector has a bias input, and the RF detector includes:
a transistor having a current terminal and a control terminal, the current terminal coupled to the RF detector output, and the control terminal coupled to the RF detector input; and
a resistor coupled between the bias input and the control terminal.

9. The circuit of claim 8, wherein the transistor includes a BJT.

10. The circuit of claim 8, wherein the RF detector input is a first RF detector input, the current terminal is a first current terminal, the control terminal is a first control terminal, and the resistor is a first resistor, the RF detector has a second RF detector input and includes:
a second transistor having a second current terminal and a second control terminal, the second current terminal coupled to the RF detector output, and the second control terminal coupled to the second RF detector input; and
a second resistor coupled between the bias input and the second control terminal.

11. The circuit of claim 8, wherein the resistor is a first resistor, the Vt multiplication circuit is a first multiplication circuit having a first multiplier terminal, and the circuit further comprises:
a second Vt multiplication circuit having a second multiplier terminal coupled to the bias input; and
a second resistor coupled between a power terminal and the second multiplier terminal.

12. The circuit of claim 11, wherein the second Vt multiplication circuit includes a diode-connected BJT coupled to the second multiplier terminal.

13. The circuit of claim 1, wherein the RF detector and the Vt multiplier circuit are part of a power detector.

14. A circuit, comprising:
a radio frequency (RF) detector having an RF detector input and an RF detector output, the RF detector configured to provide a first signal at the RF detector output responsive to a second signal at the RF detector input; and
a processing circuit having a processing terminal coupled to the RF detector output, the processing circuit configured to provide a third signal at the terminal based on scaling the first signal by a factor that is proportional to temperature.

15. The circuit of claim 14, wherein the factor is based on Vt.

16. The circuit of claim 14, wherein the processing circuit includes a diode-connected BJT coupled to the processing terminal.

17. The circuit of claim 16, wherein the processing circuit has a processing output, the BJT is a first BJT, the processing circuit further includes a second diode-connected BJT coupled to the processing output, and the first and second diode-connected BJTs have different current densities.

18. The circuit of claim 17, wherein the processing circuit further includes:
a first transistor coupled between the processing terminal and the first diode-connected BJT, the first transistor having a first control terminal coupled to the processing terminal;
a second transistor coupled to the processing output, the second transistor having a second control terminal coupled to the first control terminal; and
a resistor coupled between second transistor and the second diode-connected BJT.

19. The circuit of claim 14, wherein the RF detector has a bias input, and the circuit further comprises:
a BJT having a collector terminal and a base terminal, the collector terminal coupled to the base terminal and the bias input; and
a resistor coupled between a power terminal and the base terminal.

20. A power detector circuit comprising:
a first BJT having a first base terminal and a first collector terminal, the first base terminal coupled to a power detector input;
a current mirror having a current mirror input and a current mirror output, the current mirror input coupled to the first collector terminal;
a second BJT being diode-connected and coupled to the current mirror output;
a first transistor coupled between the current mirror output and the second BJT, the first transistor having a first control terminal and a first current terminal coupled to the current mirror output;
a third BJT being diode-connected, and the second and third BJTs having different current densities;
a second transistor having a second current terminal coupled to a power detector output, the second transistor having a second control terminal coupled to the first control terminal; and
a resistor coupled between the second transistor and the third BJT.

21. The power detector circuit of claim 20, wherein the resistor is a first resistor, and the power detector circuit further comprises:
a fourth BJT being diode-connected;
a second resistor coupled between a power terminal and the fourth BJT; and
a third resistor coupled between the fourth base terminal and the first base terminal.
